(19) United States
(12) Patent Application Publication
(10) Pub. No.: US 2007/0090509 A1
(43) Pub. Date: Apr. 26, 2007

(54) Electromagnetic interference circuit package shield

(75) Inventors: Michael Furlotti, San Francisco, CA (US); Jonathan Betts-LaCroix, San Mateo, CA (US)

Correspondence Address: Trellis Intellectual Property Law Group, PC, 1900 EMBARCADERO ROAD, SUITE 109, PALO ALTO, CA, 94303, US

(73) Assignee: OQO, Inc., San Francisco, CA (US)

(21) Appl. No.: 11/580,212

(22) Filed: Oct. 12, 2006

Related U.S. Application Data
(60) Provisional application No. 60/727,017, filed on Oct. 14, 2005.

(51) Int. Cl. H01L 23/48

(52) U.S. Cl. 257/690

(57) ABSTRACT

In one embodiment, a shielding includes one or more contact elements configured to electrically contact one or more electrical elements of an integrated circuit package. The one or more electrical elements may be located on a top surface of the package. A bottom surface of the package may be coupled to a circuit board. The one or more contact elements provide a path for a ground through the one or more electrical elements. For example, the shielding may be coupled to a ground on the circuit board. This may provide shielding of EMI.

### CROSS REFERENCES TO RELATED APPLICATIONS

This application claims priority from commonly assigned provisional patent application entitled “INTEGRAL EMI CIRCUIT PACKAGE”, application No. 60/727,017, filed Oct. 14, 2005 the entire disclosure of which is herein incorporated by reference.

### BACKGROUND

Embodiments of the present invention generally relate to electromagnetic interference (EMI) shielding.

In larger devices, such as laptop computers, devices may emit noise that may interfere with other components. However, because of the size of a laptop computer, these components may be spaced sufficiently away from each other such that they do not interfere with each other's operation. However, as portable devices are becoming smaller and smaller, these components may be placed closer and closer together. Thus, there is a chance that interference may result because of the noise radiating from the components.

### SUMMARY

Embodiments of the present invention generally relate to an electromagnetic interference (EMI) shielding for an integrated circuit package in portable devices.

In one embodiment, a shielding includes one or more contact elements configured to electrically contact one or more electrical elements of an integrated circuit package. The one or more electrical elements may be located on a top surface of the package. A bottom surface of the package may be coupled to a circuit board. The one or more contact elements provide a path for a ground through the one or more electrical elements. For example, the shielding may be coupled to a ground on the circuit board. This may provide shielding of EMI.

Further, a heat sink may be provided that may also contact the one or more contact elements. The heat sink may also contact the package through an aperture in the apparatus to provide heat dissipation. Electrical currents may flow from the electrical elements through the one or more contact elements to the heat sink. This may also provide shielding of EMI. Accordingly, any noise from the integrated circuit may be shielded and may not interfere with components in a device, such as a radio, that is located near the integrated circuit. This may be useful in portable devices that have been miniaturized where components need to be placed substantially near an integrated circuit.

In one embodiment, an apparatus is provided. The apparatus comprises: one or more contact elements configured to electrically contact one or more electrical elements of a package for an integrated circuit, the electrical element located on a top surface of the package, which is coupled to a circuit board on a bottom surface of the package, wherein the one or more contact elements provide a ground for the package through the one or more electrical elements.

In another embodiment, a system is provided. The system comprises: a package including an integrated circuit; and a shielding device comprising: one or more contact elements configured to electrically contact one or more electrical elements of the package for the integrated circuit, the electrical element located on a top surface of the package, which is coupled to a circuit board on a bottom surface of the package, wherein the one or more contact elements provide a ground for the package through the one or more electrical elements.

In yet another embodiment, a portable device is provided. The portable device comprises: a package including an integrated circuit; and a shielding device comprising: one or more contact elements configured to electrically contact one or more electrical elements of the package for the integrated circuit, the electrical element located on a top surface of the package, which is coupled to a circuit board on a bottom surface of the package, wherein the one or more contact elements provide a ground for the package through the one or more electrical elements.

A further understanding of the nature and the advantages of particular embodiments disclosed herein may be realized by reference of the remaining portions of the specification and the attached drawings.

### BRIEF DESCRIPTION OF THE DRAWINGS

FIG. 1 shows an example device that may include a shielding according to one embodiment of the present invention.

FIG. 2 depicts a system according to one embodiment of the present invention.

FIG. 3A shows an embodiment of a contact element according to one embodiment of the present invention.

FIG. 3B shows an embodiment of a contact element being flexed using spring force according to one embodiment of the present invention.

FIG. 4 shows an embodiment of system with a shielding coupled to a package according to one embodiment of the present invention.

### DETAILED DESCRIPTION OF EMBODIMENTS

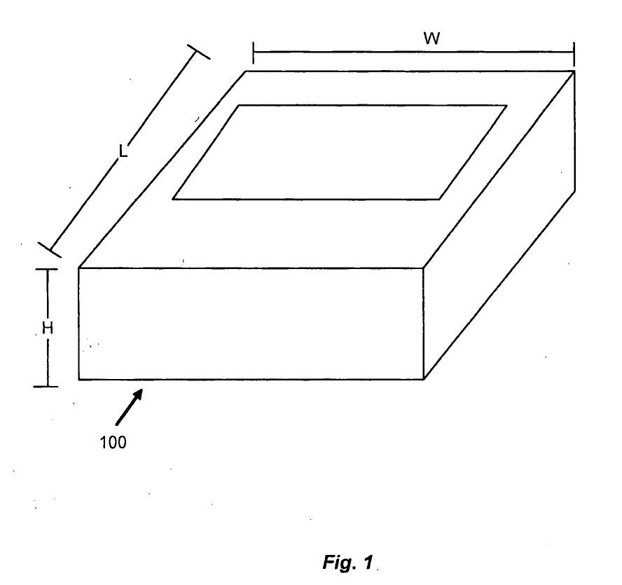

FIG. 1 shows an example device 100 that may include a shielding according to one embodiment of the present invention. In one embodiment, device 100 may be a portable device. For example, device 500 may include a miniature computer, laptop computer, personal computer, personal digital assistant (PDA), cellular telephone, Blackberry device, pocket PC, etc. In other embodiments, device 100 is not limited to portable devices and may include any computing device, such as a laptop computer, television, DVD display player, set-top box, etc.

In one embodiment, the dimensions of device 100 may be a length, L, of substantially 4 inches; a width, W, of substantially 3 inches; and a height, H, of substantially ¾ inches. Additionally, the display may be a little under substantially 3 inches wide and substantially 4 inches long.

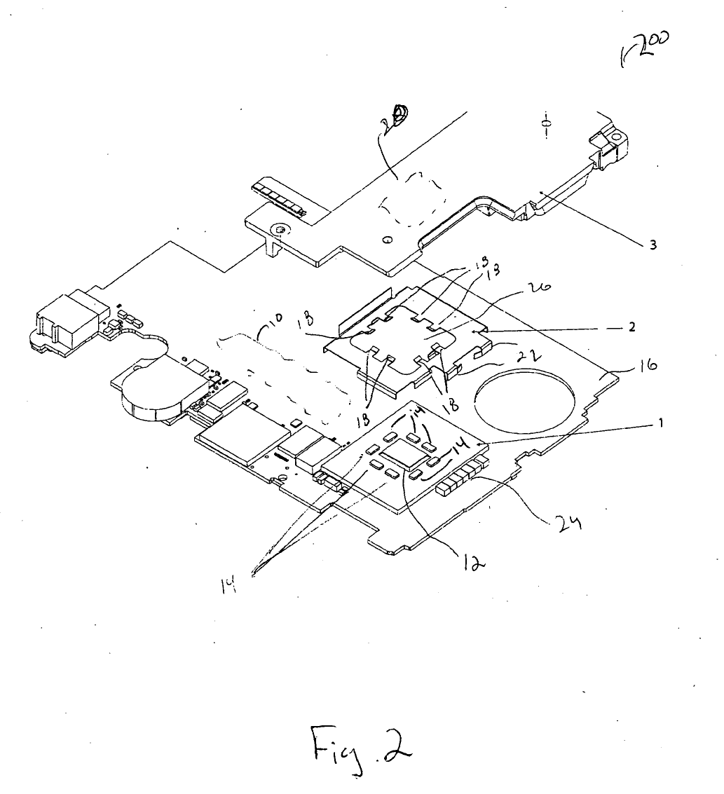

FIG. 2 depicts a system 200 according to one embodiment of the present invention. As shown, a package 1, shielding 2, heat sink assembly 3, and radio 10 are shown. In one embodiment, device 100 may include system 200; however, it will be understood that other devices may include system 200. Other components may also be included in system 200.

Package 1 may be any integrated circuit package that may house an integrated circuit 12. Package 1 may be any packaging, semiconductor device assembly, encapsulation or seal of integrated circuit 12, etc.

Integrated circuit 12 may be any electronic circuit. For example, integrated circuit 12 may be a microprocessor or any other processor.

Integrated circuit 12 may radiate noise during its operation. Noise may be any radio frequency (RF) or electromagnetic signals. The noise may be referred to EMI, which may be any electromagnetic, radio frequency, or other electrical noise. For example, noise may originate from various clock and data signals of integrated circuit 12. The noise from integrated circuit 12 may couple into other circuits inside device 100. The noise may affect performance of other components in device 100. Also, the noise may couple outside the enclosure of device 100, thus making compliance testing more difficult because the noise interferes with the test being performed.

In one embodiment, the noise may interfere with components in device 100, such as radio 10. Radio 10 may be any wireless transmitting radio, such as an 802.11, 802.15, global positioning system radios (GPS), or any other WiFi or Bluetooth radio. Further, radios may also be cellular transceivers, i.e. global system for mobile communications (GSM), code division multiplex access (CDMA), etc. It will be understood that other generations of radios will also be appreciated by persons skilled in the art and future generations may also be covered in addition to other protocols.

In one example, EMI may occur at certain distances based on the current being conducted. For example, the EMI may be a factor of 1/R, where R is a radius from the component emitting the EMI.

Shielding 2 is used to shield the noise emitted from integrated circuit 12. The shielding of the noise may be not only shield radio 10 but also shield other components in device 100 from noise. For example, antennas, coax cables connecting antennas, radio cables or other non RF interconnect connecting a device to external connectors (such as USB or video port), peripherals mounted on the side of the chassis, LCD, LED indicators, switches, fingerprint scanners, track pads, openings in the chassis, etc. Further, shielding 2 may also shield noise from outside devices, such as devices that are performing testing on device 100.

Shielding 2 may be made of a conductive material, such as any metal. Shielding 2 may be a metal box or any other electrically isolating, thermally conducting shield. In one embodiment, shielding 2 may be a metal insert or clip. It is designed to clip onto package 1 in such a way that it does not need to be soldered to a circuit board 16. In other embodiments, shielding 2 may be soldered or attached to board 16. Circuit board 16 may be board configured to hold and support components of system 200, and may also provide electrical connection between some components.

Package 1 includes one or more electrical elements 14. Electrical elements 14 may be any elements that may conduct electricity and/or store energy. In one embodiment, electrical elements 14 may be a capacitor, resistors, other circuit pieces, etc. Further, contact elements 18 may connect directly to package 1. In this case, electrical elements 14 may be the package and not capacitors. Thus, the term electrical element thus may mean any part of package 2 that can conduct electricity. The capacitor is configured to store energy in an electric field between a pair of closely-spaced conductors.

One or more contact elements 18 are configured to electrically contact one or more electrical elements 14. Electrically contact may be physically contacting one contact element 18 to another electrical element 14. However, physical contact may not be necessary if electrical current can flow from electrical elements 14 to contact elements 18. Accordingly, electrically contact may be any configuration or coupling where electrical current may flow between two elements.

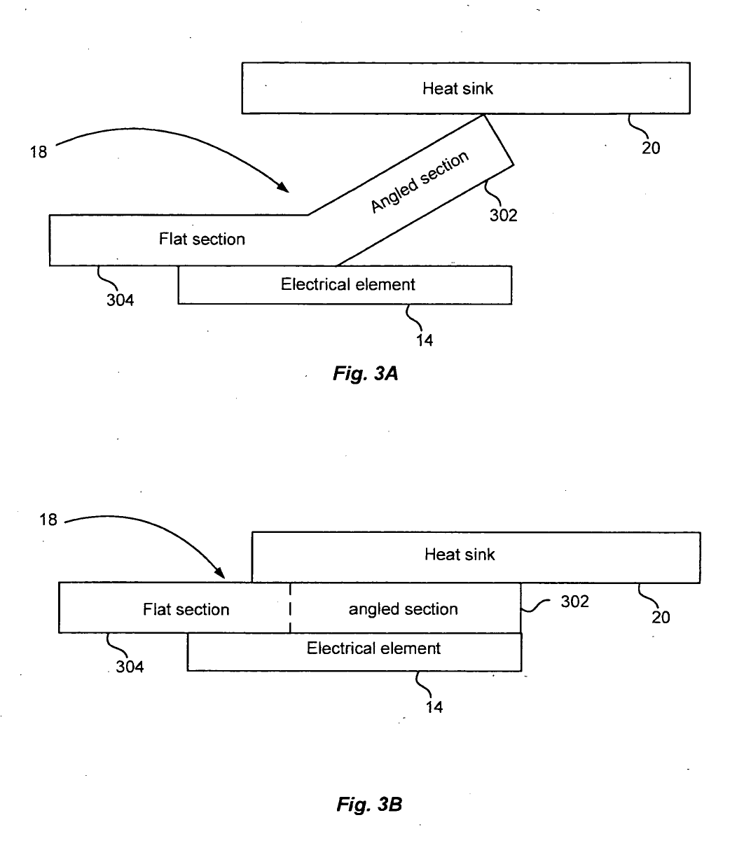

In one embodiment, contact elements 18 may be spring elements that when pushed from above at the angled section, the flat section contacts electrical elements 14. FIG. 3A shows an embodiment of contact element 18 according to one embodiment of the present invention. As shown, heat sink 20 is placed on top of an angled section 302. This provides a spring force in a downward direction. This may cause a flat section 304 to contact electrical element 14. Accordingly, using spring force, contacting element 18 can be easily electrically contacted with both electrical element 14 and heat sink 20. Although heat sink 20 is described as contacting contact element 18, any part of heat sink assembly 3 may be placed on contact element 18.

Accordingly, electrical currents may flow from electrical elements 14 through contact elements 18 to heat sink 20. In this way, shielding of electrical magnetic interference (EMI) is provided.

The shielding is provided because the radiated energy flows through contact elements 18 into heat sink 20 instead of radiating outward into device 100. Heat sink 20 is directly connected to a ground such that any induced currents are shunted to the ground through a low impedance path rather than resonating and re-radiating where the energy is not wanted. For example, the signals may flow through electrical elements 14 and contact elements 18 through grounding elements 22 to de-coupling capacitors 24. De-coupling capacitors 24 may be mounted on a power supply of board 16. The grounding elements 22 contact de-coupling capacitors 24 and form a ground. This provides a ground for the electrical current. Further, as the current runs directly into heat sink 20, this also becomes a ground. Because of the structure of system 200, the impedance in the clock noise return path is reduced and thus shields noise from other components in device 100. In this way, the induced currents are shunted to the ground through a low impedance path rather than resonating and re-radiating through device 100. A small current loop may be created by the ground. Magnetic field strength is related to the area of a current loop and by minimizing this area, the field strength of radiated energy decreases. Similarly, inductance is related to magnetic field strength. By reducing field strengths, inductance decreases in a signal path. Because signals are generally constrained to exist on metal layers of board 16, the set of geometries for current paths is limited. By creating additional current loops from the grounds on top of package 1 to grounds on top of the power supply decoupling capacitors 24, smaller current loops may be created. These loops are to some degree free of the constraints on board 16 as they occur in the z dimension while the circuitry in the top layer of board 16 exists in the x and y dimensions. Although decoupling capacitors are described as providing the ground, the ground may be provided in other ways.

Heat sink 20 is also configured to fit through an aperture 26 found in shielding 2. Heat sink 20 may then contact the top of integrated circuit 12 of package 1. This provides better heat dissipation because of the close proximity between heat sink 20 and the top of integrated circuit 12.

Package 1 may include intentional breaches that allow for heat transfer, electrical connections, limited EMI input or output, mechanical access or other features that require permeability of electrically isolating a protective layer. The breach is a space for a die to come in contact with heat sink 20. If shield 2 were continuous above processor 12 (e.g., the die) thereby covering it, heat transfer from the die would be impeded. Since the heat sink is also metal, the springs cause heat sink 20 itself to become part of shield 2 over the die.

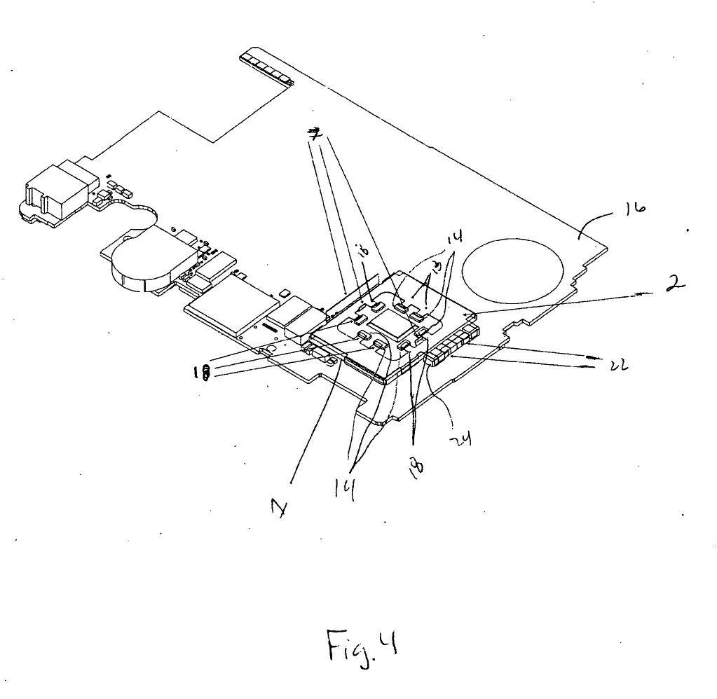

FIG. 4 shows an embodiment of system 200 with shielding 2 coupled to package 1 according to one embodiment of the present invention. As shown, one or more contact elements 18 electrically contact one or more electrical elements 14. Although not shown, heat sink assembly 3 may be placed on top of the angled section of contact elements 18 thus providing a spring action to contact both heat sink assembly 3 and electrical elements 14. This allows the contacting of electrical elements 14, contact elements 18 and heat sink assembly 3 without any soldering or other connection mechanism. In other embodiments, it will be recognized that other methods of contacting the three elements may be appreciated.

Also, as shown, grounding elements 22 contact de-coupling capacitors 24 of the power supply for board 16. Accordingly, the ground may be provided from electrical elements 14 through contact elements 18 and grounding elements 22 to de-coupling capacitors 24.

Vertical tabs 7 may make electrical contact with heat sink assembly 3. This provides additional electrical connectivity to heat sink assembly 3. Vertical tabs 7 also serve to fit shielding with heat sink assembly 3 such that shielding 2 can be slipped on to package 1 and also hold in place heat sink assembly 3. Vertical tabs 7 press shielding 2 into package 1, causing contact elements 18 to flex on top of electrical elements 14. FIG. 3B shows an example of contact element 18 where the spring action has flexed angled section 302 to contact electrical element 14. This flexing action impedes oxidation of the solder on electrical elements 14, may cause any flux to crack, and improves electrical contact. The spring action of contact elements 18 also may be used to center shielding 2 on package 1. It is a self aligning force since electrical elements 14 are placed symmetrically on package 1. Elements 14 are placed precisely symmetrically onto package 1. Each of tabs 18 press against one of the elements 14, thus the whole system fits snugly and aligns due to the countervailing forces of each of the elements 14 on each of the tabs 18. But, contact elements 18 do not have to be symmetric and self aligning.

As shown, shielding 2 slides over package 1. In one embodiment, the structure of shielding 2 allows it to be slid over and firmly attached to shielding 2. This configuration may not need shielding 2 to be soldered to board 16. However, in other embodiments, shielding 2 may be soldered to board 16.

In one embodiment, the grounding provided by shielding 2 is not directly connected to board 16. That is, shield 2 is not attached to board 16. Conventionally, the ground path is from a ball grid array (BGA) packaged part through the leads of the part (or balls) into board 16. This ground path is on the bottom of package 1 and serves to connect package 1 to board 16. In this case, the leakage current flowing through the substrate of processor 12 into heat sink 20, since the die substrate and metal heat sink 20 form a parallel plate capacitor. Because heat sink 20 may be imperfectly grounded, this current path may be rather long (>1 inch) through heat sink 20 into a corner of board 16, back to the ground plane of board 20 to the BGA ground balls. Having a ground return path 5 mm away from the substrate through contact elements 18 into the cap mounted on package 1 reduces the current loop significantly.

Thus, as discussed above, by providing a ground to decoupling capacitors 24 from the top of package 1, the impedance is lowered and thus EMI is shielded from other components of device 100. The current path from decoupling capacitors 24 to package 1 may be more in parallel than a path through the BGA. Thus, inductance adds 1/L when in parallel. This improves the ground path for any induced current in heat sink 20, and the power supply capacitors 24 are a convenient source of ground.

Embodiments of the present invention provide many advantages. For example, shielding 2 does not significantly increase the footprint of the component on board 16. Also, shielding 2 may be designed and installed without the consideration of circuitry and components surrounding package 1. This is because of its thin profile.

Also, designers may design board 16 using components that do not include integral EMI shielding. These components may be shielded using shielding 2 once EMI issues are identified on a working circuit board 16. This allows designers to work with components with minimal footprints while also allowing EMI shields to be inserted as needed. This may be useful when miniaturization of designs is important, such as in handheld computers and portable electronic devices. EMI may become major issues in these smaller devices because radios 10 and integrated circuit 12 may be placed closer together. Also, other components may also experience interference.

Additionally, shielding 2 may be useful when it is not feasible to ground a component directly to board 16. By allowing the ground to be contacted on the top of a component, grounding on the bottom to board 16 is not necessary. This may provide flexibility to designers.

Although the description has been described with respect to particular embodiments thereof, these particular embodiments are merely illustrative, and not restrictive. For example, the shielding may shield noise from any component and not just a microprocessor.

Any suitable programming language can be used to implement the routines of particular embodiments including C, C++, Java, assembly language, etc. Different programming techniques can be employed such as procedural or object oriented. The routines can execute on a single processing device or multiple processors. Although the steps, operations, or computations may be presented in a specific order, this order may be changed in different particular embodiments. In some particular embodiments, multiple steps shown as sequential in this specification can be performed at the same time. The sequence of operations described herein can be interrupted, suspended, or otherwise controlled by another process, such as an operating system, kernel, etc. The routines can operate in an operating system environment or as stand-alone routines occupying all, or a substantial part, of the system processing. Functions can be performed in hardware, software, or a combination of both. Unless otherwise stated, functions may also be performed manually, in whole or in part.

In the description herein, numerous specific details are provided, such as examples of components and/or methods, to provide a thorough understanding of particular embodiments. One skilled in the relevant art will recognize, however, that a particular embodiment can be practiced without one or more of the specific details, or with other apparatus, systems, assemblies, methods, components, materials, parts, and/or the like. In other instances, well-known structures, materials, or operations are not specifically shown or described in detail to avoid obscuring aspects of particular embodiments.

A “computer-readable medium” for purposes of particular embodiments may be any medium that can contain, store, communicate, propagate, or transport the program for use by or in connection with the instruction execution system, apparatus, system, or device. The computer readable medium can be, by way of example only but not by limitation, an electronic, magnetic, optical, electromagnetic, infrared, or semiconductor system, apparatus, system, device, propagation medium, or computer memory.

Particular embodiments can be implemented in the form of control logic in software or hardware or a combination of both. The control logic, when executed by one or more processors, may be operable to perform that what is described in particular embodiments.

A “processor” or “process” includes any human, hardware and/or software system, mechanism or component that processes data, signals, or other information. A processor can include a system with a general-purpose central processing unit, multiple processing units, dedicated circuitry for achieving functionality, or other systems. Processing need not be limited to a geographic location, or have temporal limitations. For example, a processor can perform its functions in “real time,” “offline,” in a “batch mode,” etc. Portions of processing can be performed at different times and at different locations, by different (or the same) processing systems.

Reference throughout this specification to “one embodiment”, “an embodiment”, “a specific embodiment”, or “particular embodiment” means that a particular feature, structure, or characteristic described in connection with the particular embodiment is included in at least one embodiment and not necessarily in all particular embodiments. Thus, respective appearances of the phrases “in a particular embodiment”, “in an embodiment”, or “in a specific embodiment” in various places throughout this specification are not necessarily referring to the same embodiment. Furthermore, the particular features, structures, or characteristics of any specific embodiment may be combined in any suitable manner with one or more other particular embodiments. It is to be understood that other variations and modifications of the particular embodiments described and illustrated herein are possible in light of the teachings herein and are to be considered as part of the spirit and scope.

Particular embodiments may be implemented by using a programmed general purpose digital computer, by using application specific integrated circuits, programmable logic devices, field programmable gate arrays, optical, chemical, biological, quantum or nanoengineered systems, components and mechanisms may be used. In general, the functions of particular embodiments can be achieved by any means as is known in the art. Distributed, networked systems, components, and/or circuits can be used. Communication, or transfer, of data may be wired, wireless, or by any other means.

It will also be appreciated that one or more of the elements depicted in the drawings/figures can also be implemented in a more separated or integrated manner, or even removed or rendered as inoperable in certain cases, as is useful in accordance with a particular application. It is also within the spirit and scope to implement a program or code that can be stored in a machine-readable medium to permit a computer to perform any of the methods described above.

Additionally, any signal arrows in the drawings/Figures should be considered only as exemplary, and not limiting, unless otherwise specifically noted. Furthermore, the term “or” as used herein is generally intended to mean “and/or” unless otherwise indicated. Combinations of components or steps will also be considered as being noted, where terminology is foreseen as rendering the ability to separate or combine is unclear.

As used in the description herein and throughout the claims that follow, “a”, “an”, and “the” includes plural references unless the context clearly dictates otherwise. Also, as used in the description herein and throughout the claims that follow, the meaning of “in” includes “in” and “on” unless the context clearly dictates otherwise.

The foregoing description of illustrated particular embodiments, including what is described in the Abstract, is not intended to be exhaustive or to limit the invention to the precise forms disclosed herein. While specific particular embodiments of, and examples for, the invention are described herein for illustrative purposes only, various equivalent modifications are possible within the spirit and scope, as those skilled in the relevant art will recognize and appreciate. As indicated, these modifications may be made to the present invention in light of the foregoing description of illustrated particular embodiments and are to be included within the spirit and scope.

Thus, while the present invention has been described herein with reference to particular embodiments thereof, a latitude of modification, various changes and substitutions are intended in the foregoing disclosures, and it will be appreciated that in some instances some features of particular embodiments will be employed without a corresponding use of other features without departing from the scope and spirit as set forth. Therefore, many modifications may be made to adapt a particular situation or material to the essential scope and spirit. It is intended that the invention not be limited to the particular terms used in following claims and/or to the particular embodiment disclosed as the best mode contemplated for carrying out this invention, but that the invention will include any and all particular embodiments and equivalents falling within the scope of the appended claims.

We claim:

1. An apparatus comprising:
one or more contact elements configured to electrically contact one or more electrical elements of a package for an integrated circuit, the electrical element located on a top surface of the package, which is coupled to a circuit board on a bottom surface of the package,
wherein the one or more contact elements provide a ground for the package through the one or more electrical elements.

2. The apparatus of claim 1, wherein at least one of the one or more contact elements contact a heat sink.

3. The apparatus of claim 2, wherein the heat sink does not contact the circuit board.

4. The apparatus of claim 2, wherein electrical currents flow from the one or more electrical elements through the one or more contact elements to the heat sink, wherein the apparatus provides shielding of electrical magnetic interference (EMI).

5. The apparatus of claim 2, wherein the apparatus comprises an aperture that allows the heat sink to contact the package through the aperture.

6. The apparatus of claim 1, further comprising one or more grounding contact elements configured to contact a grounding element on the circuit board.

7. The apparatus of claim 1, wherein the apparatus is configured to shield EMI from a radio situated in a portable device housing the apparatus, package, and the radio.

8. The apparatus of claim 1, wherein the apparatus is configured to cover the package.

9. The apparatus of claim 8, wherein the apparatus is attached to the circuit board.

10. The apparatus of claim 8, wherein the apparatus is not attached to the circuit board.

11. The apparatus of claim 1, wherein the one or more electrical elements comprise a capacitor.

12. A system comprising:
a package including an integrated circuit; and
a shielding device comprising:
one or more contact elements configured to electrically contact one or more electrical elements of the package for the integrated circuit, the electrical element located on a top surface of the package, which is coupled to a circuit board on a bottom surface of the package,
wherein the one or more contact elements provide a ground for the package through the one or more electrical elements.

13. The system of claim 12, further comprising a heat sink, wherein at least one of the one or more contact elements contact the heat sink.

14. The system of claim 14, wherein the heat sink does not contact the circuit board.

15. The system of claim 14, wherein electrical currents flow from the one or more electrical elements through the one or more contact elements to the heat sink, wherein the apparatus provides shielding of electrical magnetic interference (EMI).

16. The system of claim 14, wherein the shielding device comprises an aperture that allows the heat sink to contact the package through the aperture.

17. The system of claim 12, further comprising one or more grounding contact elements configured to contact a grounding element on the circuit board.

18. The system of claim 12, further comprising a radio, wherein the shielding device is configured to shield EMI from a radio situated in a portable device housing the shielding device, package, and the radio.

19. The system of claim 12, wherein the one or more electrical elements comprise a capacitor.

20. A portable device comprising:
a package including an integrated circuit; and
a shielding device comprising:
one or more contact elements configured to electrically contact one or more electrical elements of the package for the integrated circuit, the electrical element located on a top surface of the package, which is coupled to a circuit board on a bottom surface of the package,
wherein the one or more contact elements provide a ground for the package through the one or more electrical elements.
